(19) United States
(12) Patent Application Publication
(10) Pub. No.: US 2011/0102968 A1
(43) Pub. Date: May 5, 2011

(54) MULTILAYER STRUCTURE, CAPACITOR INCLUDING THE MULTILAYER STRUCTURE AND METHOD OF FORMING THE SAME

(75) Inventors: Jae-Hyoung CHOI, Hwaseong-si (KR); Youn-Soo Kim, Yongin-si (KR); Jung-Hyeon Kim, Hwaseong-si (KR); Wan-Don Kim, Yongin-si (KR); Jae-Soon Lim, Seoul (KR); Sang-Yeol Kang, Seoul (KR)

(73) Assignee: Samsung Electronics Co., Ltd.

(21) Appl. No.: 12/838,296

(22) Filed: Jul. 16, 2010

(30) Foreign Application Priority Data
Jul. 20, 2009 (KR) 10-2009-0065739

(51) Int. Cl. H01G 4/008; B32B 9/04; B05D 5/12; C23C 14/34

(52) U.S. Cl. 361/305; 428/698; 427/79; 204/192.22

(57) ABSTRACT

In a multilayer structure and a method of forming the same, a conductive layer including a metal nitride and a dielectric layer positioned on a surface of the conductive layer and having a high dielectric constant. The metal nitride comprises one of niobium, vanadium and compositions thereof. Thus, the EOT and leakage current of the multilayer structure may be sufficiently improved.

### CROSS-REFERENCE TO RELATED APPLICATIONS

This application claims the benefit of Korean Patent Application No. 10-2009-0065739, filed on Jul. 20, 2009, in the Korean Intellectual Property Office, the disclosure of which is incorporated herein in its entirety by reference.

### BACKGROUND

1. Field

Example embodiments relate to a multilayer structure, a capacitor including the same and a method of forming the capacitor. More particularly, example embodiments relate to a multilayer structure in which a plurality of unit layers is stacked and a capacitor including the multilayered structure and method of forming the capacitor.

2. Description of the Related Art

A capacitor for a recent integrated circuit device becomes difficult to have high capacitance gradually as the integration degree of the integrated circuit device is increased, and thus various researches have been conducted for increasing the capacitance of the capacitor. Due to the researches, it has been known that the smaller the thickness of a dielectric layer of a capacitor, the greater the capacitance of the capacitor is. Thus, the dielectric layer of the capacitor generally comprises materials having high dielectric constant so as to reduce an equivalent oxide thickness (EOT) of the dielectric layer with respect to an electrode layer which usually comprises silicon oxide. When the capacitor includes a dielectric layer comprising materials of high dielectric constant, the electrode layer of the capacitor may comprise metal in place of polysilicon. However, there has been known that the boundary area between the metal electrode and the dielectric layer is usually transformed due to heat, to thereby increase leakage current from the capacitor.

### SUMMARY

Example embodiments provide a multilayer structure of which the boundary area between neighboring unit layers is stable without any deformations.

Other example embodiments provide a capacitor for a semiconductor device having a low leakage current and high capacitance.

Still other example embodiments provide a method of forming the above capacitor for a semiconductor device.

According to some example embodiments, there is provided a multilayered structure of which the boundary area between neighboring unit layers is stable without any deformations. The multilayer structure may include a conductive layer comprising a metal nitride and a dielectric layer positioned on a surface of the conductive layer and having a high dielectric constant. The metal nitride may comprise one of niobium, vanadium and compositions thereof.

In an example embodiment, the metal nitride includes one of a cubic crystal structure and a hexagonal crystal structure and a composition ratio of metal and nitrogen is in a range of about 1:0.8 to about 1:1.3.

In an example embodiment, the dielectric layer includes an oxide or an oxynitride comprising a metal selected from the group consisting of zirconium (Zr), hafnium (Hf), aluminum (Al), silicon (Si), tantalum (Ta), titanium (Ti) and compositions thereof.

According to other example embodiments, there is provided a capacitor for a semiconductor device. The capacitor may include a first electrode, a second electrode facing the first electrode and a dielectric layer interposed between the first and second electrodes in such a configuration that at least one of the first and second electrodes comprises metal nitride including one of vanadium, niobium and compositions thereof.

In an example embodiment, the metal nitride includes one of a cubic crystal structure and a hexagonal crystal structure and a composition ratio of metal and nitrogen is in a range of about 1:0.8 to about 1:1.3.

According to still other example embodiments, there is provided method of forming the above capacitor for a semiconductor device. At first, a lower electrode may be formed on a substrate and a dielectric layer may be formed on the lower electrode. An upper electrode may be formed on the dielectric layer. In such case, at least one of the first and second electrodes comprises metal nitride including one of vanadium, niobium and compositions thereof.

In an example embodiment, the lower and upper electrodes may be formed on the following steps: a preliminary metal nitride layer may be formed on a base. The base may include the substrate or the dielectric layer. Then, the preliminary metal nitride layer may be nitrified by a heat treatment, to thereby transform the preliminary metal nitride layer to the metal nitride layer.

In an example embodiment, the preliminary metal nitride layer is formed by a sputtering process using argon (Ar) gases and nitrogen (N2) gases as a source gas on condition that a composition ratio of argon and nitrogen is in a range of about 1:1 to about 1:2.

In an example embodiment, the heat treatment is performed at a temperature of about 200° C. to about 800° C. in a nitrogen gas (N2) or an ammonium (NH3) gas atmosphere.

According to some example embodiments of the present inventive concept, the multilayer structure includes a conductive layer comprising a metal nitride and a dialectic layer in such a configuration that the metal nitride layer includes vanadium, niobium and compositions thereof. Thus, the multilayer structure in a semiconductor device may sufficiently reduce the EOT and leakage current from the multilayer structure, to thereby improve electronic characteristics of the semiconductor device.

### BRIEF DESCRIPTION OF THE DRAWINGS

Example embodiments will be more clearly understood from the following detailed description taken in conjunction with the accompanying drawings.

FIG. 1 is a cross-sectional view illustrating a multilayer structure in accordance with an example embodiment of the present inventive concept;

FIG. 2 is a cross-sectional view illustrating a capacitor including the multilayer structure shown in FIG. 1;

FIGS. 3 to 6 are cross-sectional views illustrating processing steps for a method of forming the capacitor shown in FIG. 2;

FIG. 7 is a cross-sectional view illustrating a capacitor in accordance with another example embodiment of the present inventive concept;

FIGS. 8 to 10 are cross-sectional views illustrating processing steps for a method of forming the capacitor shown in FIG. 7;

FIG. 11 is a cross-sectional view illustrating a capacitor in accordance with still another example embodiment of the present inventive concept;

FIG. 12 is cross-sectional view illustrating a capacitor in accordance with further still another example embodiment of the present inventive concept;

FIG. 13 is a cross-sectional view illustrating a transistor including the multilayer structure shown in FIG. 1 in accordance with an example embodiment of the present inventive concept;

FIG. 14 is a cross-sectional view illustrating a transistor including the multilayer structure shown in FIG. 1 in accordance with another example embodiment of the present inventive concept;

FIG. 15 is a cross-sectional view illustrating a transistor including the multilayer structure shown in FIG. 1 in accordance with still another example embodiment of the present inventive concept;

FIG. 16 is a block diagram illustrating an electronic system using the transistor in accordance with an example embodiment of the present inventive concept;

FIG. 17 is a graph showing relations between a voltage applied to capacitor and a leakage current from the capacitor when the first and second embodiments of the capacitor of the present inventive concept and the first to third comparative examples of the conventional capacitors were experimented;

FIG. 18 is a graph showing a required voltage with respect to an equivalent oxide thickness (EOT) on condition that the current of about 1×10⁻⁷ A/cm² may path through a capacitor when the first embodiment of the present inventive capacitor and the first comparative example of the conventional capacitor were experimented;

FIG. 19 is a graph showing relations between a voltage applied to capacitor and a leakage current from the capacitor when the first, third and fourth embodiments of the capacitor of the present inventive concept and the first comparative examples of the conventional capacitors were experimented;

FIG. 20 is a graph showing a required voltage with respect to an equivalent oxide thickness (EOT) on condition that the current of about 1×10⁻⁷ A/cm² may path through a capacitor when the first, third and fourth embodiment of the present inventive capacitor and the first comparative example of the conventional capacitor were experimented; and

FIGS. 21 and 22 are graphs showing a crystal structure of a niobium nitride layer analyzed by an x-ray diffraction (XRD) inspector.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the twins “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

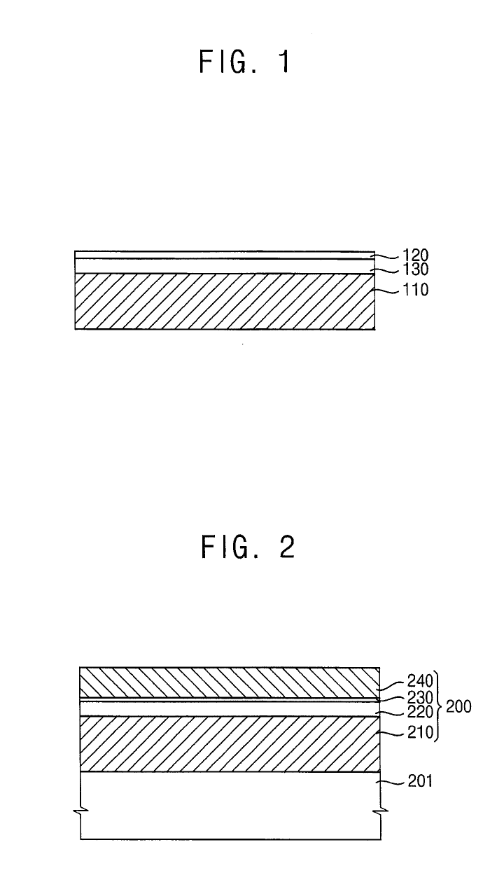

FIG. 1 is a cross-sectional view illustrating a multilayer structure in accordance with an example embodiment of the present inventive concept.

Referring to FIG. 1, a multilayer structure 100 in accordance with an example embodiment of the present inventive concept may include a conductive layer 110 and a dielectric layer 120.

For example, the conductive layer 100 may comprise metal nitride including one of vanadium (V), niobium (Nb) and compositions thereof. In the present example embodiment, the conductive layer 100 may comprise vanadium nitride or niobium nitride.

A composition ratio of metal and nitrogen (N) in the metal nitride may be in a range of about 1:0.8 to about 1:1.3. The metal nitride may have a tetragonal crystal structure, a cubic crystal structure, a hexagonal crystal structure and a mixture thereof under the above composition ratio of metal and nitrogen (N). For example, when the composition ratio of metal and nitrogen (N) is about 1:0.75, the metal nitride may be exemplarily composed of Nb₄N₃ and the conductive layer 110 may have exemplarily a tetragonal crystal structure. In contrast, when the composition ratio of metal and nitrogen (N) is about 1:1, the metal nitride may be exemplarily composed of NbN and the conductive layer 110 may have exemplarily a cubic or a hexagonal crystal structure.

In the present example embodiment, the conductive layer 110 may have a hexagonal crystal structure and an additional layer 130 having high dielectric constant may be further formed between the hexagonal-crystallized conductive layer 110 and the dielectric layer 120. Thus, an unexpected layer (not shown) having relatively low dielectric constant may be sufficiently prevented from being formed between the conductive layer 110 and the dialectic layer 120, to thereby prevent the reduction of the permittivity of the capacitor.

In addition, the metal nitride may have a relatively high work function of about 4.6 eV to about 4.8 eV. Thus, when a capacitor may include the conductive layer 110 comprising metal nitride and the dielectric layer 120, the work function difference between conductive layer and a dielectric layer may be increased in the capacitor, to thereby minimize the leakage current from the capacitor.

The dielectric layer 120 may face the conductive layer 110. Thus, the dielectric layer 120 may be formed on the conductive layer 110 or the conductive layer 110 may be formed on the dielectric layer 120.

For example, the dielectric layer may comprise metal oxide of which the dialectic constant may be higher than that of oxide-nitride-oxide (ONO) dielectric structure.

The dielectric layer may comprise two component materials. Examples of the two component materials may include zirconium oxide (ZrO), hafnium oxide (HfO), titanium oxide (TiO), scandium oxide (ScO), aluminum oxide (AlO), strontium oxide (SrO), yttrium oxide (YO), lanthanum oxide (LaO), silicon oxide (SiO), etc. These may be used alone or in combinations thereof.

In contrast, the dielectric layer 120 may comprise three-or-more component materials having a perovskite crystal structure. Examples of the three-or-more component materials may include (Ba, Sr)TiO3(BST), SrTiO3, BaTiO3, PZT, PLZT, (Ba,Sr)(Zr,Ti)O3(BSZTO), Sr(Zr,Ti)O3(SZTO), Ba(Zr,Ti)O3(BZTO), (Ba,Sr)ZrO3(BSZO), SrZrO3, BaZrO3, etc. These may be used alone or in combinations thereof.

In the present example embodiment, the dielectric layer 120 may comprise metal oxide or metal oxynitride having band gap energy of about 4.0 eV or more.

The additional layer 130 may be formed in a boundary area of the conductive layer 110 and the dielectric layer 120 by a heat treatment and may have a relatively dielectric constant. That is, the additional layer 130 may be formed by chemical reactions of the conductive layer 110 and the dielectric layer 120 due to the heat treatment. Thus, the multilayer may have a relatively high dielectric constant due to the addition layer 130 having a high dielectric constant.

In the present example embodiment, the metal of the metal oxide in the dielectric layer 120 and the metal of the metal nitride in the conductive layer 110 may be included in different groups in a periodic table. For example, the metal in the conductive layer 110 may include metal elements in Group 5B in the periodic table and the metal in the dialectic layer 120 may include metal elements in Group 4B in the periodic table such as zirconium (Zr) and hafnium (Hf) or metal elements in Group 3A such aluminum (Al).

FIG. 2 is a cross-sectional view illustrating a capacitor including the multilayer structure shown in FIG. 1.

Referring to FIG. 2, a capacitor 200 in accordance with an example embodiment of the present inventive concept may include a first electrode 210, a second electrode 240 and a dielectric layer 220 interposed between the first and second electrodes 220 and 240. The capacitor 200 may be positioned on a substrate 201 such as a wafer including various conductive structures.

The substrate 201 may include a semiconductor substrate and a single crystalline substrate having a metal oxide. For example, the substrate 201 may include a silicon substrate, germanium substrate, silicon-germanium substrate, silicon-on-insulating (SOI) substrate, germanium-on-insulating (GOI) substrate, aluminum oxide substrate and titanium oxide substrate.

The first electrode 210 may be formed on the substrate 201 and may comprise a first conductive material such as a metal, a metal alloy or a metal nitride. Examples of the first conductive materials may include platinum (Pt), ruthenium (Ru), iridium (Ir), palladium (Pd), gold (Au), platinum-manganese (Pt—Mn) alloy, iridium-ruthenium (Ir—Ru) alloy, titanium (Ti), tungsten (W), tantalum (Ta), strontium-ruthenium oxide (SrRuO3: BRO), calcium-ruthenium oxide (CaRuO3: CRO), barium-strontium-ruthenium oxide ((Ba,Sr)RuO3: BSR), titanium nitride, tungsten nitride, tantalum nitride, hafnium nitride, zirconium nitride, titanium aluminum nitride, tantalum silicon nitride, titanium silicon nitride, tantalum aluminum nitride, etc. These may be used alone or in combinations thereof. The first electrode 210 may include a multilayered structure in which each unit layer comprises one of the first conductive materials.

The dielectric layer 220 may be formed on the first electrode 210 and may comprise a dielectric material having relatively high dialectic constant. For example, the dielectric layer 220 may comprise two component materials. Examples of the two component materials may include zirconium oxide (ZrO), hafnium oxide (HfO), titanium oxide (TiO), scandium oxide (ScO), aluminum oxide (AlO), strontium oxide (SrO), yttrium oxide (YO), lanthanum oxide (LaO), silicon oxide (SiO), etc. These may be used alone or in combinations thereof.

In contrast, the dielectric layer 220 may comprise three-or-more component materials having a perovskite crystal structure. Examples of the three-or-more component materials may include (Ba, Sr)TiO3(BST), SrTiO3, BaTiO3, PZT, PLZT, (Ba,Sr)(Zr,Ti)O3(BSZTO), Sr(Zr,Ti)O3(SZTO), Ba(Zr,Ti)O3(BZTO), (Ba,Sr)ZrO3(BSZO), SrZrO3, BaZrO3, etc. These may be used alone or in combinations thereof.

In the present example embodiment, the dielectric layer 220 may comprise metal oxide or metal oxynitride having band gap energy of about 4.0 eV or more.

For example, the second electrode 240 may comprise metal nitride including one of vanadium (V), niobium (Nb) and compositions thereof. In the present example embodiment, the second electrode 240 may comprise vanadium nitride or niobium nitride.

A composition ratio of metal and, nitrogen (N) in the metal nitride may be in a range of about 1:0.8 to about 1:1.3. The metal nitride may have a tetragonal crystal structure, a cubic crystal structure, a hexagonal crystal structure and a mixture thereof under the above composition ratio of metal and nitrogen (N). For example, when the composition ratio of metal and nitrogen (N) is about 1:0.75, the metal nitride may be exemplarily composed of Nb₄N₃ and the conductive layer 110 may have exemplarily a tetragonal crystal structure.

In contrast, when the composition ratio of metal and nitrogen (N) in the metal nitride is about 1:1, the metal nitride may be exemplarily composed of NbN and the second electrode 240 may have exemplarily a cubic or a hexagonal crystal structure.

In the present example embodiment, the second electrode 240 may have a hexagonal crystal structure and an additional layer 230 having high dielectric constant may be further formed between the hexagonal-crystallized second electrode 240 and the dielectric layer 220. Thus, an unexpected layer (not shown) having relatively low dielectric constant may be sufficiently prevented from being formed between the second electrode 240 and the dialectic layer 220, to thereby prevent the reduction of the permittivity of the capacitor.

In addition, the metal nitride may have a relatively high work function of about 4.6 eV to about 4.8 eV. Thus, the work function difference between the second electrode 240 and the dielectric layer 220 may be increased in the capacitor 200, to thereby minimize the leakage current from the capacitor 200.

For example, the capacitor 200 may further include the additional layer 230 that may be positioned in a boundary area of the second electrode 240 and the dielectric layer 220 and may have a relatively dielectric constant. That is, the additional layer 230 may be formed by chemical reactions of the second electrode 240 and the dielectric layer 120 due to a heat treatment. Thus, the capacitor 200 may have a relatively high dielectric constant due to the additional layer 230 having a high dielectric constant.

In the present example embodiment, the metal of the metal oxide in the dielectric layer 220 and the metal of the metal nitride in the second electrode 240 may be included in different groups in a periodic table. For example, the metal in the second electrode 240 may include metal elements in Group 5B in the periodic table and the metal in the dialectic layer 220 may include metal elements in Group 4B in the periodic table such as zirconium (Zr) and hafnium (Hf) or metal elements in Group 3A such aluminum (Al).

In a modified example embodiment, the first electrode 210 may also comprise metal nitride such as vanadium nitride and niobium nitride in place of the second electrode 240. In such a case, the addition layer 230 may also be interposed between the first electrode 210 and the dielectric layer 220.

In another modified example embodiment, both of the first and second electrodes 210 and 240 may also comprise metal nitride such as vanadium nitride and niobium nitride. In such a case, the addition layer 230 may be interposed between the first electrode 210 and the dielectric layer 220 and between the second electrode 240 and the dielectric layer 220.

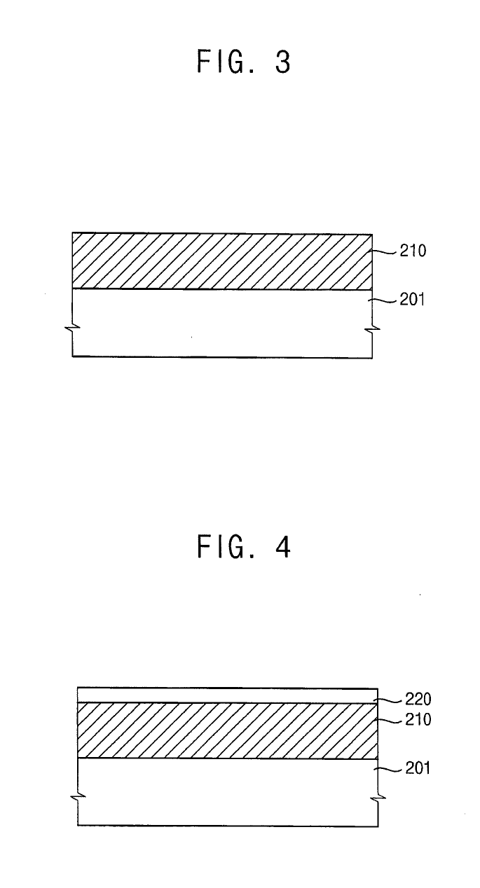

FIGS. 3 to 6 are cross-sectional views illustrating processing steps for a method of forming the capacitor shown in FIG. 2.

Referring to FIG. 3, the substrate 210 may be prepared for forming the capacitor 200 thereon. For example, the substrate 201 may include a silicon substrate, germanium substrate, silicon-germanium substrate, silicon-on-insulating (SOI) substrate, germanium-on-insulating (GOI) substrate, aluminum oxide substrate and titanium oxide substrate. In addition, various lower conductive structures may be formed on the substrate 201. The lower conductive structure may include a contact pad, a conductive pattern, a metal wiring, a gate structure and a transistor.

Then, the first electrode 210 may be formed on the substrate 201 by one of an atomic layer deposition (ALD) process, a sputtering process, an electron beam deposition (EBD) process, a chemical vapor deposition (CVD) process and a pulse laser deposition (PLD) process. The first electrode 210 may comprise a first conductive material such as a metal, a metal alloy or a metal nitride. Examples of the first conductive materials may include platinum (Pt), ruthenium (Ru), iridium (Ir), palladium (Pd), gold (Au), platinum-manganese (Pt—Mn) alloy, iridium-ruthenium (Ir—Ru) alloy, titanium (Ti), tungsten (W), tantalum (Ta), strontium-ruthenium oxide (SrRuO3: BRO), calcium-ruthenium oxide (CaRuO3: CRO), barium-strontium-ruthenium oxide ((Ba,Sr)RuO3: BSR), titanium nitride, tungsten nitride, tantalum nitride, hafnium nitride, zirconium nitride, titanium aluminum nitride, tantalum silicon nitride, titanium silicon nitride, tantalum aluminum nitride, etc. These may be used alone or in combinations thereof. The first electrode 210 may include a multilayered structure in which each unit layer comprises one of the first conductive materials.

In the present example embodiment, the first electrode 210 may be fanned on the substrate 201 by an ALD process and may comprise a conductive metal alloy having a perovskite crystal structure. The first electrode 210 may include a single layer structure or a multilayer structure.

A first additional process may be further performed on the first electrode 210 for improving electrical characteristics of the first electrode 210. The first additional process may include a heat treatment, ozone (O3) treatment, oxygen (O2) treatment and a plasma treatment.

Referring to FIG. 4, the dielectric layer 220 may be formed on the first electrode 210 to a thickness of about 50 Å to about 100 Å and may comprise a metal compound. For example, the dielectric layer 220 may comprise two component materials. Examples of the two component materials may include zirconium oxide (ZrO), hafnium oxide (HfO), titanium oxide (TiO), scandium oxide (ScO), aluminum oxide (AlO), strontium oxide (SrO), yttrium oxide (YO), lanthanum oxide (LaO), silicon oxide (SiO), etc. These may be used alone or in combinations thereof.

The dielectric layer 220 may be formed by one of a sputtering process, a PLD process, an EBD process and an ALD process. Particularly, the dielectric layer 220 may be formed by an ALD process, to thereby accurately control the thickness thereof and improve the step coverage thereof on the first electrode 210.

A second additional process may be further performed on the dielectric layer 220 for improving electrical characteristics of the dielectric layer 220. The second additional process may include a heat treatment, ozone (O3) treatment, oxygen (O2) treatment and a plasma treatment.

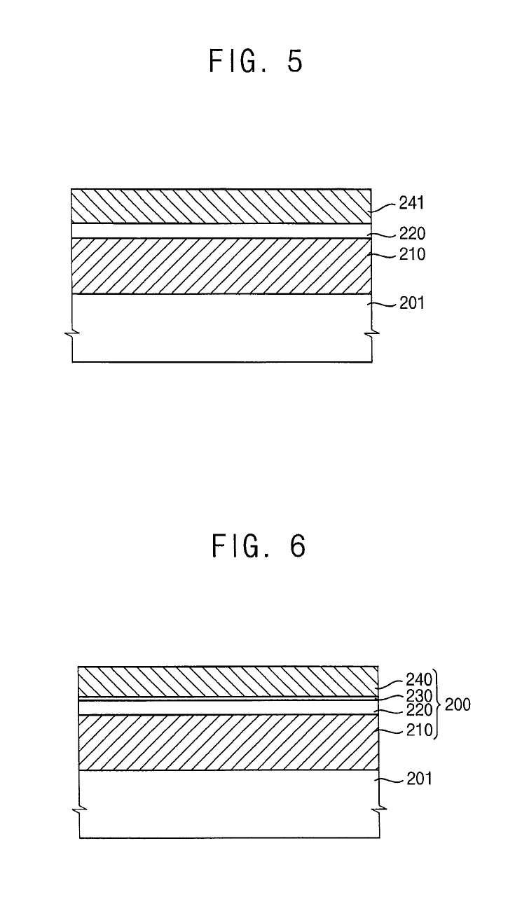

Referring to FIG. 5, a preliminary metal nitride layer 241 may be formed on the dielectric layer 220. The preliminary metal nitride layer 241 may comprise metal nitride such as vanadium nitride and niobium nitride.

The preliminary metal nitride layer 241 may be formed by one of a sputtering process, a PLD process, an EBD process and an ALD process. Particularly, the preliminary metal nitride layer 241 may be formed by an ALD process, to thereby accurately control the thickness thereof and improve the step coverage thereof on the dielectric layer 220.

In the present example embodiment, the preliminary metal nitride layer 241 may be formed by a sputtering process in a process chamber power by a direct current (DC) power of about 0.5 kW to about 20 kW at a pressure less than about 0.5 mTorr and a temperature of about a room temperature to about 450° C. In the sputtering process, argon (Ar) gases may be used as a sputtering gas and nitrogen (N) gases may be further supplied into the process chamber.

A mass flow ratio of the argon (Ar) and the nitrogen (N) may be in a range of about 1:1 to about 1:2 in the above sputtering process. When the mass flow of the nitrogen (N) gases may be lower than that of the argon (Ar) gases in the sputtering process, the leakage current may be rapidly increased in the capacitor 200 despite reduction of the EOT of the preliminary metal nitride layer 241. In contrast, when the mass flow of the nitrogen (N) gases may be lower than that of the argon (Ar) gases in the sputtering process, the leakage current may be rapidly increased in the capacitor 200 despite reduction of the EOT of the preliminary metal nitride layer 241.

In a modified example embodiment, the preliminary metal nitride layer 241 may be formed by a CVD process or an ALD process. When performing an ALD process, source gases such as niobium or vanadium gases may be supplied onto the dielectric layer 220, and thus atoms of the source gases may be absorbed onto the dielectric layer 220. For example, when niobium gases may be used as the source gases in the ALD process, niobium compounds may be used as a precursor for the absorption onto the dielectric layer 220. Examples of the niobium compounds may include NbI5, NbF6, Nb[N(CH3)2]5, Nb(NtBu)[(C2H5)2C2]3, Nb[N(C2H5)2]3, Nb[O(C2H5)4][OCH2CH2N(CH3)2], Nb(OC2H5)5, Nb(OCH3)5 and combinations thereof. Particularly, the absorption of the source gases onto the substrate 201 may be performed at a temperature of about 200° C. to about 400° C., to thereby improve crystallization of the preliminary metal nitride layer 241. Then, a purge gas may be supplied into the process chamber, and non-reacted source gases, which may be drifting in the process chamber, may be removed from the process chamber by the purge gases. For example, inactive gases such as nitrogen (N2) gases and argon (Ar) gases may be used as the purge gases. Thereafter, nitrogen-based reaction gases such as nitrogen (N2) gases and ammonium (NH3) gases may be supplied into the process chamber and the atoms of the source gases and the nitrogen atom may be reacted with each other on the dielectric layer 220, to thereby form the preliminary metal nitride layer 241 on the dielectric layer 220. In the present example embodiment, the preliminary metal nitride layer 241 may comprise vanadium nitride or niobium nitride. Finally, non-reacted reaction gases and byproducts of the chemical reaction, which may be drifting in the process chamber, may be removed from the process chamber. The sequential performance of the source gas supply, the purge gas supply, the reaction gas supply and the purge gas supply may complete a unit cycle of the ALD process for forming the preliminary metal nitride layer 241. Thus, the repetition of the unit cycle of the ALD process may determine the thickness of the preliminary metal nitride layer 241. Therefore, the crystallized preliminary metal nitride layer 241 may be formed on the dielectric layer 220 to a desired thickness by repetition of the unit cycle of the ALD process.

In the present example embodiment, the metal of the metal oxide in the dielectric layer 220 and the metal of the metal nitride in the preliminary metal nitride layer 241 may be included in different groups in a periodic table. For example, the metal in the preliminary metal nitride layer 241 may include metal elements in Group 5B in the periodic table such as vanadium (V) and niobium (Nb) and the metal in the dialectic layer 220 may include metal elements in Group 4B in the periodic table such as zirconium (Zr) and hafnium (Hf) or metal elements in Group 3A such aluminum (Al).

Referring to FIG. 6, a heat treatment may be performed on the preliminary metal nitride layer 241 in a nitrogen atmosphere, to thereby transform the preliminary metal nitride layer 241 into the second electrode 240 having an improved crystal structure. Thus, the second electrode 240 may be formed on the dielectric layer 220 through the transformation of the preliminary metal nitride layer 241 due to the heat treatment.

Particularly, the heat treatment may be performed in a nitrogen atmosphere or an ammonium atmosphere, thus the composition ration of nitrogen (N) may be increased in the preliminary metal nitride layer 241 and the crystal structure of the second electrode 240 may be improved by the heat treatment in a nitrogen atmosphere or an ammonium atmosphere. For example, the second electrode 240 may have a tetragonal crystal structure, a cubic crystal structure, a hexagonal crystal structure and a mixture thereof. In the present example embodiment, the nitrogen composition ratio of nitrogen may be increased in the second electrode 240 due to the heat treatment in the nitrogen or ammonium atmosphere, the second electrode 240 may be formed into the cubic crystal structure or the hexagonal crystal structure. For example, the heat treatment may include a furnace heat treatment or a rapid thermal process (RTP).

In the present example embodiment, the heat treatment may be performed at a temperature of about 200° C. to about 800° C. When the heat treatment may be performed at a temperature below about 200° C., the nitrogen atoms may be insufficiently penetrated into the preliminary metal nitride layer 241, which would reduce crystallization rate of the preliminary metal nitride layer 241. In contrast, when the heat treatment may be performed at a temperature over about 800° C., the dielectric layer 220 under the second electrode 240 may tend to be deteriorated due to the heat. Accordingly, the heat treatment may be performed at a temperature in a range of about 200° C. to about 800° C.

In the present example embodiment, the second electrode 240 may have a hexagonal crystal structure and the additional layer 230 having high dielectric constant may be further formed at the boundary area of the hexagonal-crystallized second electrode 240 and the dielectric layer 220. That is, when the second electrode 240 may comprise metal nitride and the dielectric layer 220 may comprise metal oxide having a relatively high dielectric constant, the metal nitride layer and the metal oxide layer may be chemically reacted with each other in a subsequent high temperature process, to thereby form the additional layer 230 of which the dielectric constant may be relatively high between the second electrode 240 and the dielectric layer 220. Thus, the whole dielectric constant of the capacitor 200 may also be improved due to the additional layer 230.

In addition, the metal nitride of the second electrode 240 may have a relatively high work function of about 4.6 eV to about 4.8 eV. Thus, the work function difference between the second electrode 240 and the dielectric layer 220 may be increased in the capacitor 200, to thereby minimize the leakage current from the capacitor 200.

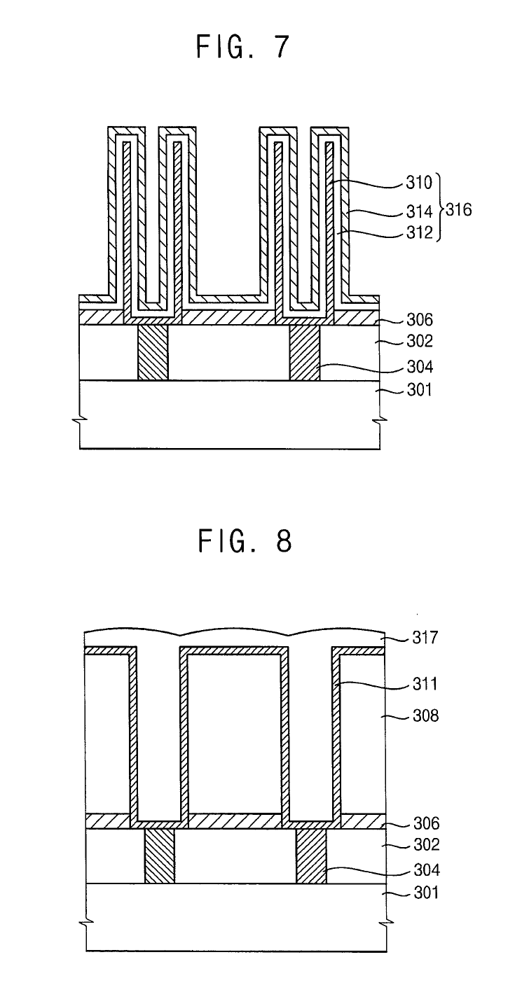

FIG. 7 is a cross-sectional view illustrating a capacitor in accordance with another example embodiment of the present inventive concept.

Referring to FIG. 7, an insulation interlayer 302 may be formed on a substrate 301. At least one contact plug 302 may penetrate through the insulation interlayer 302 and may make contact with the substrate 301. In the present example embodiment, a plurality of the contact plugs 302 may be arranged in a regular manner on the substrate 301 and various conductive structures such as transistors and metal wirings may also be arranged on the substrate 301.

A plurality of cylindrical lower electrodes 310 may be arranged on the insulation interlayer 302. A bottom surface of the lower electrode 310 may make electrical contact with a top surface of the contact plug 304. The lower electrode 310 may comprise substantially the same material as the first electrode of the capacitor shown in FIG. 2, and thus any further detailed descriptions on the materials of the lower electrode 310 will be omitted.

An etch stop layer 306 may be positioned on the insulation interlayer 302 between the lower electrodes 310. For example, the etch stop layer 306 may comprise silicon nitride.

A dielectric layer 312 may be positioned on sidewalls and bottom of the lower electrode 310 and on the etch stop layer 306. The dielectric layer 312 may comprise substantially the same materials as the dielectric layer of the capacitor shown in FIG. 2, thus any further detailed descriptions on the dielectric layer 312 will be omitted.

An upper electrode 314 may be positioned on the dielectric layer 312. The upper electrode 314 may also comprise substantially the same materials as the second electrode of the capacitor shown in FIG. 2, thus any further detailed descriptions on the upper electrode 314 will be omitted.

Accordingly, the cylindrical capacitor 300 may have an enlarged contact area between the lower electrode 310 and the dielectric layer 312, to thereby improve capacitance.

FIGS. 8 to 10 are cross-sectional views illustrating processing steps for a method of forming the capacitor shown in FIG. 7.

Referring to FIG. 8, various conductive structures such as transistors and metal wirings may be formed on the substrate 301 and the insulation interlayer 302 may be formed on the substrate 301 to a sufficient thickness to cover the conductive structures. Then, the insulation interlayer 302 may be partially removed from the substrate 301 by an etching process, to thereby form a plurality of contact holes (not shown) through which an upper surface of the substrate 301 may be partially exposed.

A conductive layer (not shown) may be formed on the insulation interlayer 302 to a sufficient thickness to fill up the contact holes, and then may be partially removed from the insulation interlayer 302 by a planarization process until the upper surface of the insulation interlayer 302 may be exposed. As a result of the planarization process, the conductive layer may merely remain in the contact hole, to thereby form a plurality of the contact plugs 304 in the contact holes, respectively.

An etch stop layer 306 may be formed on the insulation interlayer 302 by a CVD process and may comprise silicon nitride. Thereafter, a mold layer (not shown) may be formed on the etch stop layer 306. Since the lower electrode 310 may function as a sacrificial layer for forming the lower electrode 310, the mold layer may be formed to be higher or equal to the lower electrode 310. The mold layer may need to be removed from the etch stop layer 306 by a wet etching process and the etching rate of the mold layer may need to be higher than that of the etch stop layer 306 in the same etchant. For that reasons, the mold layer may comprise a silicon oxide such as boron phosphorus silicate glass (BPSG), tetraethyl orthosilicate (TEOS) deposited by high density plasma or plasma enhanced CVD process (HDP or PE-TEOS) and tone silazene (TOSZ).

Then, the mold layer may be removed from the substrate 301 including the etch stop layer 306 and the etch stop layer 306 may be subsequently removed from the substrate 301, to thereby form a mold pattern 308 having a plurality of openings (not shown) through which the upper surface of the substrate 301 may be exposed. The lower electrode 310 may be formed in the openings in a subsequent process.

A first conductive layer 311 may be formed on a sidewall and a bottom of the openings and on an upper surface of the mold pattern 308 in accordance with an upper profile of the mold pattern 308. In the present example embodiment, the first conductive layer 311 may comprise substantially the same materials including a metal as the first electrode of the capacitor shown in FIG. 2. Further, the first conductive layer 311 may be formed by the same process as described with reference to FIG. 3 for forming the first electrode.

Then, a sacrificial layer 317 may be formed on the mold pattern 308 to a sufficient thickness to fill up the opening. For example, the sacrificial layer 317 may comprise a material having substantially the same properties as the mold pattern 308. In the present example embodiment, the sacrificial layer 317 may comprise silicon oxide.

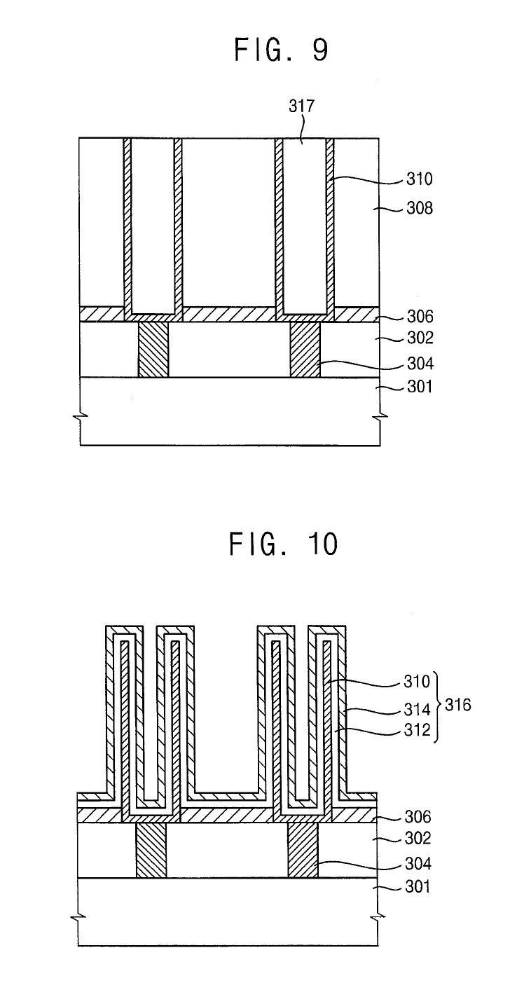

Referring to FIG. 9, the sacrificial layer 317 and the first conductive layer 311 may be partially removed from the mold pattern 308 by a planarization process until an upper surface of the mold pattern 308 may be exposed, and thus the sacrificial layer 317 and the first conductive layer 311 may just remain in the opening. That is, the first conducive layer 311 may be formed into the lower electrode 310 in the sidewalls of the opening and the opening may be filled up with the residuals of the sacrificial layer 317.

Referring the FIG. 10, the mold pattern 308 and the residuals of the sacrificial layer 317 may be removed from the substrate 301 by an etching process in such a manner that the damage to the cylindrical lower electrode 310 may be minimized in the etching process. For example, a wet etching process may be used as the etching process.

Therefore, the cylindrical lower electrode 310 may remain on the insulation interlayer 302 that is covered with the etch stop layer 306, and thus inner and outer sidewalls of the lower electrode 310 may be exposed to surroundings.

Thereafter, the dielectric layer 312 may be formed on the etch stop layer 306 and the outer and inner surfaces of the lower electrode 310 according to a profile of the lower electrode 310. An upper electrode 314 may be formed on the dielectric layer 312 by a deposition process. The dielectric layer 312 and the upper electrode 314 may comprise the same material as the dielectric layer and the second electrode of the capacitor shown in FIG. 2, and may be formed by the same processes as described with reference to FIGS. 4 to 6 for forming the dielectric layer 312 and the upper electrode 314. Thus, any further detailed descriptions on the dielectric layer 312 and the upper electrode 314 will be omitted.

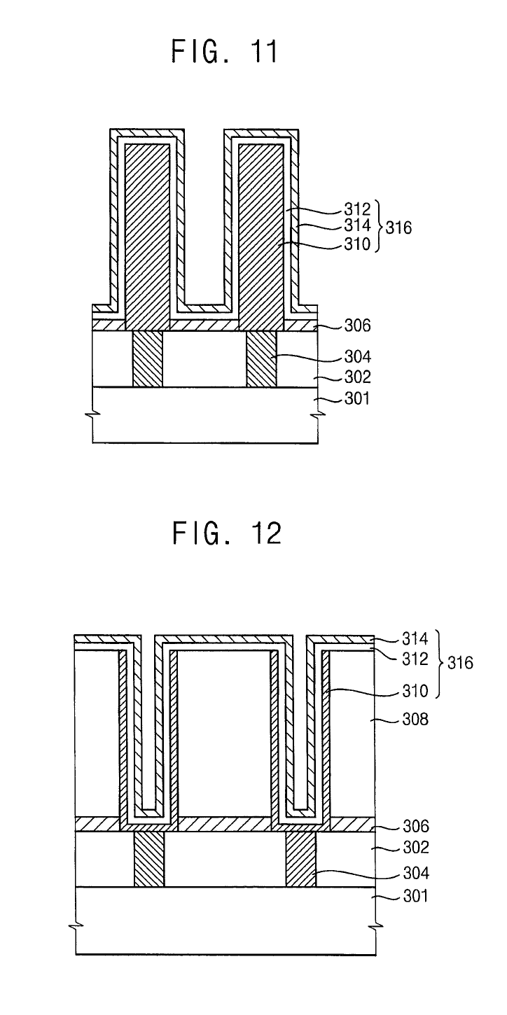

FIG. 11 is a cross-sectional view illustrating a capacitor in accordance with still another example embodiment of the present inventive concept.

Referring to FIG. 11, a capacitor 316 in accordance with an example embodiment of the present inventive concept may include a lower electrode 310, a dielectric layer 312 and an upper electrode 314 that may be stacked on a substrate 301. For example, various conductive structures such as transistors and metal wirings may be formed on the substrate 301 and an insulation interlayer 302 may be formed on the substrate 301 to a sufficient thickness to cover the conductive structures. A plurality of contact plugs 304 may penetrate through the insulation interlayer 302 and may make electrical contact with the underlying conductive structures on the substrate 301.

A plurality of pillar-shaped lower electrodes 310 may be arranged on the insulation interlayer 302. A bottom surface of the lower electrode 310 may make electrical contact with a top surface of the contact plug 304. The lower electrode 310 may comprise substantially the same material as the first electrode of the capacitor shown in FIG. 2, and thus any further detailed descriptions on the materials of the lower electrode 310 will be omitted.

An etch stop layer 306 may be positioned on the insulation interlayer 302 between the lower electrodes 310. For example, the etch stop layer 306 may comprise silicon nitride.

A dielectric layer 312 may be positioned on sidewalls and bottom of the lower electrode 310 and on the etch stop layer 306. The dielectric layer 312 may comprise substantially the same materials as the dielectric layer of the capacitor shown in FIG. 2, thus any further detailed descriptions on the dielectric layer 312 will be omitted.

An upper electrode 314 may be positioned on the dielectric layer 312 according to an upper profile of the dielectric layer 312. The upper electrode 314 may also comprise substantially the same materials as the second electrode of the capacitor shown in FIG. 2, thus any further detailed descriptions on the upper electrode 314 will be omitted.

The capacitor 316 of the present example embodiment may be formed through a similar process as described with reference to FIGS. 8 to 10, except that the openings of the mold pattern 308 may be filled up with the first conducive layer 311 without any sacrificial layer. Thus, the opening of the mold pattern 308 may be merely filled up with the lower electrode 310 without any sacrificial layer after the planarization process for partially removing of the first conductive layer 311 from the mold pattern 308. Accordingly, the lower electrode 310 in FIG. 11 may be formed into a column or a pillar shape while the electrode 310 in FIG. 7 may be formed into a hollow cylinder shape. Therefore, any further detailed descriptions on processing steps for a method of forming the capacitor in FIG. 11 will be omitted.

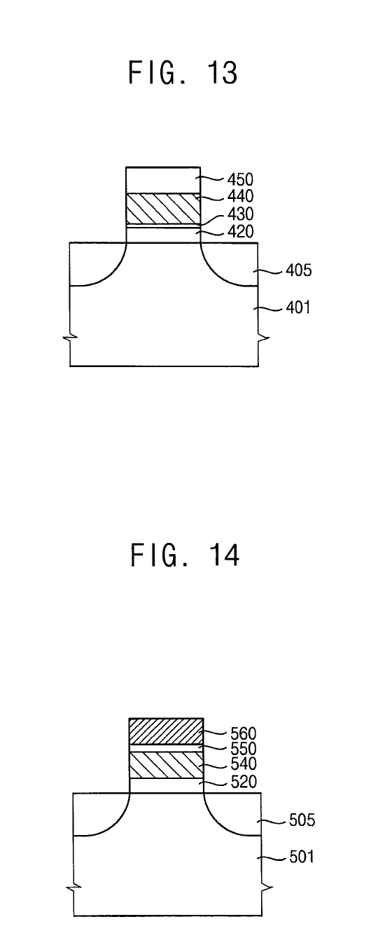

FIG. 12 is cross-sectional view illustrating a capacitor in accordance with further still another example embodiment of the present inventive concept.

Referring to FIG. 12, a capacitor 316 in accordance with an example embodiment of the present inventive concept may include a lower electrode 310, a dielectric layer 312 and an upper electrode 314 that may be stacked on a substrate 301. For example, various conductive structures such as transistors and metal wirings may be formed on the substrate 301 and an insulation interlayer 302 may be formed on the substrate 301 to a sufficient thickness to cover the conductive structures. A plurality of contact plugs 304 may penetrate through the insulation interlayer 302 and may make electrical contact with the underlying conductive structures on the substrate 301.

A plurality of concave cylindrical lower electrodes 310 may be arranged on the insulation interlayer 302. A bottom surface of the lower electrode 310 may make electrical contact with a top surface of the contact plug 304 and may have a concave structure. The lower electrode 310 may comprise substantially the same material as the first electrode of the capacitor shown in FIG. 2, and thus any further detailed descriptions on the materials of the lower electrode 310 will be omitted.

An etch stop layer 306 may be positioned on the insulation interlayer 302 between the lower electrodes 310. For example, the etch stop layer 306 may comprise silicon nitride.

A dielectric layer 312 may be positioned on sidewalls and bottom of the lower electrode 310 and on the etch stop layer 306. The dielectric layer 312 may comprise substantially the same materials as the dielectric layer of the capacitor shown in FIG. 2, thus any further detailed descriptions on the dielectric layer 312 will be omitted.

An upper electrode 314 may be positioned on the dielectric layer 312 according to an upper profile of the dielectric layer 312. The upper electrode 314 may also comprise substantially the same materials as the second electrode of the capacitor shown in FIG. 2, thus any further detailed descriptions on the upper electrode 314 will be omitted.

The capacitor 316 of the present example embodiment may be formed through a similar process as described with reference to FIGS. 8 to 10, except that the mold pattern 308 may still remain on the etch stop layer 306. Thus, the lower electrode 310, the dielectric layer 312 and the upper electrode 314 of the capacitor 316 may be formed on the sidewall and bottom of the opening of the mold pattern 308. That is, the capacitor 316 may be defined by the opening of the mold pattern 308. Accordingly, the capacitor 316 in FIG. 12 may be formed into a concave or a recessed shape while the capacitor 316 in FIG. 7 may be formed into a hollow cylinder shape or a protrusion shape. Therefore, any further detailed descriptions on processing steps for a method of forming the capacitor in FIG. 12 will be omitted.

FIG. 13 is a cross-sectional view illustrating a transistor including the multilayer structure shown in FIG. 1 in accordance with an example embodiment of the present inventive concept.

Referring to FIG. 13, a transistor in accordance with an example embodiment of the present inventive concept may include a gate insulation layer 420, a gate electrode 440 and source/drain electrodes 405 that are stacked on a substrate 401. A mask pattern 450 may be positioned on the gate electrode. A gate conductive layer may be shaped into gate electrode 440 by an etching process using the mask pattern 450 as an etching mask.

For example, the gate electrode 440 may be shaped into a line extending in a first direction and may function as a word line in the transistor.

The substrate 401 may include a semiconductor substrate and a single crystalline substrate having a metal oxide. For example, the substrate 201 may include a silicon substrate, germanium substrate, silicon-germanium substrate, silicon-on-insulating (SOI) substrate, germanium-on-insulating (GOI) substrate, aluminum oxide substrate and titanium oxide substrate.

The gate insulation layer 420 may be arranged on the substrate 401 and may comprise a metal oxide having band gap energy over about 4.0 eV. Examples of the metal oxide may include zirconium oxide (ZrO), hafnium oxide (HfO), titanium oxide (TiO), scandium oxide (ScO), aluminum oxide (AlO), strontium oxide (SrO), yttrium oxide (YO), lanthanum oxide (LaO), silicon oxide (SiO), etc. These may be used alone or in combinations thereof.

The gate electrode 440 may be positioned on the gate insulation layer 420 and may comprise metal nitride including a conductive metal such as vanadium (V) and niobium (Nb). Thus, the gate electrode 440 may comprise vanadium nitride or niobium nitride.

A composition ratio of metal and nitrogen (N) in the metal nitride may be in a range of about 1:0.8 to about 1:1.3. Thus, the gate electrode 440 comprising the metal nitride may have a tetragonal crystal structure, a cubic crystal structure, a hexagonal crystal structure and a mixture thereof under the above composition ratio of metal and nitrogen (N). For example, when the composition ratio of metal and nitrogen (N) is about 1:0.75, the metal nitride may be exemplarily composed of Nb₄N₃ and the gate electrode 440 may have exemplarily a tetragonal crystal structure.

In contrast, when the composition ratio of metal and nitrogen (N) is about 1:1, the metal nitride may be exemplarily composed of NbN and the gate electrode 440 may have exemplarily a cubic or a hexagonal crystal structure.

In the present example embodiment, the gate electrode 440 may have a cubic or a hexagonal crystal structure and an additional layer 430 having high dielectric constant may be interposed between the gate electrode 440 and the gate insulation layer 420.

In addition, the metal nitride may have a relatively high work function of about 4.6 eV to about 4.8 eV. Thus, when a transistor may include the gate electrode 440 comprising metal nitride and the gate insulation layer 420, the work function difference between the gate electrode 440 and the gate insulation layer 420 may be increased in the capacitor, to thereby minimize the leakage current from the gate electrode 440.

The transistor may further include the additional layer 430 interposed between the gate electrode 440 and the gate insulation layer 420 and having a relatively high dielectric constant. When the gate electrode 440 may comprise metal nitride and the gate insulation layer 420 may comprise an oxide having relatively high dielectric constant, the metal nitride of the gate electrode 440 and the metal oxide of the gate insulation layer 420 may be chemically reacted with each other due to a heat treatment, to thereby form the additional layer 430 at the boundary area of the gate electrode 440 and the gate insulation layer 420. Thus, the dielectric constant of the transistor may be sufficiently improved due to the addition layer 430 having a high dielectric constant.

In the present example embodiment, the metal of the metal oxide in the gate insulation layer 420 and the metal of the metal nitride in the gate electrode 440 may be included in different groups in a periodic table. For example, the metal in the gate electrode 440 may include metal elements in Group 5B in the periodic table and the metal in the gate insulation layer 420 may include metal elements in Group 4B in the periodic table such as zirconium (Zr) and hafnium (Hf) or metal elements in Group 3A such aluminum (Al).

The source/drain electrodes 405 may be positioned at surface portions of on the substrate adjacent to the stacked structure of the gate insulation layer 420 and the gate electrode 440 between which the addition layer 430 may be positioned.

FIG. 14 is a cross-sectional view illustrating a transistor including the multilayer structure shown in FIG. 1 in accordance with another example embodiment of the present inventive concept.

Referring to FIG. 14, a transistor in accordance with another example embodiment of the present inventive concept may include a tunnel insulation layer 520, a floating gate electrode 540, a dielectric pattern 550 and a control gate electrode 560 that may be stacked on a substrate 501.

The tunnel insulation layer 520 may be formed on the substrate 501 and may comprise an oxide such as silicon oxide.

The floating gate electrode 540 may be positioned on the gate insulation layer 420 and may comprise metal nitride including a conductive metal such as vanadium (V) and niobium (Nb). Thus, the floating gate electrode 540 may comprise vanadium nitride or niobium nitride.

For example, the floating gate electrode 540 may comprise substantially the same material as the gate electrode 440 shown in FIG. 13.

The dielectric pattern 550 may be arranged on the floating gate electrode 540 and may comprise a metal oxide. Examples of the metal oxide may include zirconium oxide (ZrO), hafnium oxide (HfO), titanium oxide (TiO), scandium oxide (ScO), aluminum oxide (AlO), strontium oxide (SrO), yttrium oxide (YO), lanthanum oxide (LaO), silicon oxide (SiO), etc. These may be used alone or in combinations thereof.

The control gate electrode 560 may be arranged on the dielectric layer 550 and may also comprise substantially the same material as the gate electrode 440 shown in FIG. 13.

The source/drain electrodes 505 may be positioned at surface portions of on the substrate adjacent to the stacked structure of the floating gate electrode, the dielectric pattern 550 and the control gate electrode 560.

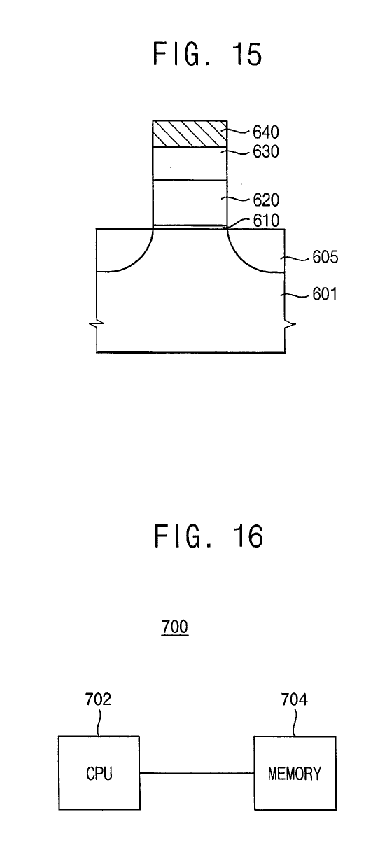

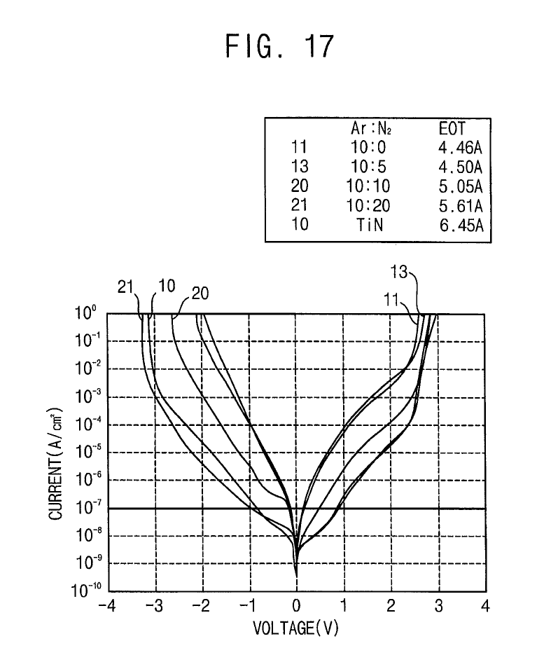

FIG. 15 is a cross-sectional view illustrating a transistor including the multilayer structure shown in FIG. 1 in accordance with still another example embodiment of the present inventive concept.

Referring to FIG. 15, a transistor in accordance with still another example embodiment of the present inventive concept may include a lower insulation layer 610, an electron trapping layer 620, an upper insulation layer 630 and a control gate electrode 640 that may be stacked on a substrate 601. Source/drain electrodes 605 may be positioned at surface portions of on the substrate 601 adjacent to the stacked structure of the lower insulation layer 610, the electron trapping layer 620, the upper insulation layer 630 and the control gate electrode 640. In the present example embodiment, the transistor may function as a non-volatile memory device.

A channel region (not shown) may be interposed between the source and the drain electrodes 605.

The lower insulation layer 610 may be arranged on the channel region of the substrate 601 and may comprise an oxide having a dielectric constant. Examples of the oxide for the lower insulation layer 610 may include zirconium oxide (ZrO), hafnium oxide (HfO), titanium oxide (TiO), scandium oxide (ScO), aluminum oxide (AlO), strontium oxide (SrO), yttrium oxide (YO), lanthanum oxide (LaO), silicon oxide (SiO), etc. These may be used alone or in combinations thereof.

The electron trapping layer 620 may be arranged on the lower insulation layer 610 and may comprise silicon nitride or silicon oxide. Electrons may move from the control gate electrode 640 into the electron trapping layer 620 through the upper insulation layer 630 by a Fowler-Nordheim tunneling method. When a relatively lower voltage may be applied to the source/drain electrodes 605, electrons may move from the channel region into the electron trapping layer 620 through the lower insulation layer 610 by a thermal electron injection method.

The upper insulation layer 630 may be positioned on the electron trapping layer 620 and may comprise a material having a relatively high dielectric constant. A relatively high permittivity of the upper insulation layer 630 may facilitate the movement of electrons through the upper insulation layer 630, and thus even a low voltage to the control gate 640 may generate a relatively large Fowler-Nordheim current through the upper insulation layer 630.

The upper insulation layer 630 may comprise substantially the same material as the lower insulation layer 610. However, the upper insulation layer 630 may comprise a material of which the permittivity may be lower than that of the lower insulation layer 610.

The control gate electrode 640 may be positioned on the upper insulation layer 630 and may comprise a metal nitride including a conductive metal such as vanadium (V) and niobium (Nb). Thus, the control gate electrode 640 may comprise vanadium nitride or niobium nitride.

The control gate electrode 640 may comprise substantially the same material as the gate electrode described with reference to FIG. 13.

The tunnel insulation layer 520 may be formed on the substrate 501 and may comprise an oxide such as silicon oxide.

Electronic System Using the Transistors

FIG. 16 is a block diagram illustrating an electronic system using the transistor in accordance with an example embodiment of the present inventive concept.

Referring to FIG. 16, an electronic system using the transistors of the present inventive concept may include a central process unit (CPU) 702 and a memory unit 704. The memory unit 704 may include a dynamic random access memory (DRAM) device and a flash memory device. A capacitor of which the electrode may comprise niobium nitride or vanadium nitride may be provided with a peripheral region and a cell region of the memory unit 704. The memory unit 704 may be electronically connected to the CPU 702 through an interconnection such as a bus line.

Although not illustrated in detail in FIG. 16, the transistor and the capacitor according to the present inventive concept may be included in the electronic system as a component in accordance with a recent digitalization of the electronic system, as would be known to one of the ordinary skill in the art.

Hereinafter, various embodiments of the present inventive concept and various examples of the conventional capacitor are provided and experimental results of comparison between the embodiments and the conventional examples are disclosed.

### Embodiment 1

In a first embodiment of the capacitor of the present inventive concept, niobium nitride was deposited onto a substrate by a sputtering process to form the lower electrode comprising niobium nitride. Then, zirconium oxide was deposited onto the lower electrode and a heat treatment was performed on the zirconium oxide layer at a temperature of about 500° C. to thereby form the dielectric layer on the lower electrode. Finally, titanium nitride was deposited onto the dielectric layer by a sputtering process to thereby form the upper electrode on the dielectric layer. In such a case, the mass flow ratio of argon (Ar) and nitrogen (N2) was maintained to be about 1:1 during the sputtering process for forming the lower electrode.

### Embodiment 2

In a second embodiment of the capacitor of the present inventive concept, niobium nitride was deposited onto a substrate by a sputtering process to form the lower electrode comprising niobium nitride. Then, zirconium oxide was deposited onto the lower electrode and a heat treatment was performed on the zirconium oxide layer at a temperature of about 500° C. to thereby form the dielectric layer on the lower electrode, Finally, titanium nitride was deposited onto the dielectric layer by a sputtering process to thereby form the upper electrode on the dielectric layer. In such a case, the mass flow ratio of argon (Ar) and nitrogen (N2) was maintained to be about 1:2 during the sputtering process for forming the lower electrode.

### Embodiment 3

In a third embodiment of the capacitor of the present inventive concept, niobium nitride was deposited onto a substrate by a sputtering process and the niobium nitride layer was further performed on a heat treatment at a temperature of about 700° C. in a nitrogen (N2) gas atmosphere to form the lower electrode comprising niobium nitride. Then, zirconium oxide was deposited onto the lower electrode and a heat treatment was performed on the zirconium oxide layer at a temperature of about 500° C. to thereby form the dielectric layer on the lower electrode. Finally, titanium nitride was deposited onto the dielectric layer by a sputtering process to thereby form the upper electrode on the dielectric layer. In such a case, the mass flow ratio of argon (Ar) and nitrogen (N2) was maintained to be about 1:1 during the sputtering process for forming the lower electrode.

### Embodiment 4

In a fourth embodiment of the capacitor of the present inventive concept, niobium nitride was deposited onto a substrate by a sputtering process and the niobium nitride layer was further performed on a heat treatment at a temperature of about 700° C. in an ammonium (NH3) gas atmosphere to form the lower electrode comprising niobium nitride. Then, zirconium oxide was deposited onto the lower electrode and a heat treatment was performed on the zirconium oxide layer at a temperature of about 500° C. to thereby form the dielectric layer on the lower electrode. Finally, titanium nitride was deposited onto the dielectric layer by a sputtering process to thereby form the upper electrode on the dielectric layer. In such a case, the mass flow ratio of argon (Ar) and nitrogen (N2) was maintained to be about 1:1 during the sputtering process for forming the lower electrode.

### Comparative Example 1

In a first conventional capacitor, titanium nitride was deposited onto a substrate by a CVD process to form the lower electrode comprising titanium nitride. Then, zirconium oxide was deposited onto the lower electrode and a heat treatment was performed on the zirconium oxide layer at a temperature of about 500° C. to thereby form the dielectric layer on the lower electrode. Finally, titanium nitride was deposited onto the dielectric layer by a sputtering process to thereby form the upper electrode on the dielectric layer.

### Comparative Example 2

In a second conventional capacitor, niobium nitride was deposited onto a substrate by a sputtering process to form the lower electrode comprising niobium nitride. Then, zirconium oxide was deposited onto the lower electrode and a heat treatment was performed on the zirconium oxide layer at a temperature of about 500° C. to thereby form the dielectric layer on the lower electrode. Finally, titanium nitride was deposited onto the dielectric layer by a sputtering process to thereby form the upper electrode on the dielectric layer. No nitrogen (N2) gases were supplied onto the substrate during the sputtering process for forming the lower electrode.

### Comparative Example 3

In a third conventional capacitor, niobium nitride was deposited onto a substrate by a sputtering process to form the lower electrode comprising niobium nitride. Then, zirconium oxide was deposited onto the lower electrode and a heat treatment was performed on the zirconium oxide layer at a temperature of about 500° C. to thereby form the dielectric layer on the lower electrode. Finally, titanium nitride was deposited onto the dielectric layer by a sputtering process to thereby form the upper electrode on the dielectric layer. In such a case, the mass flow ratio of argon (Ar) and nitrogen (N2) was maintained to be about 1:0.5 during the sputtering process for forming the lower electrode.

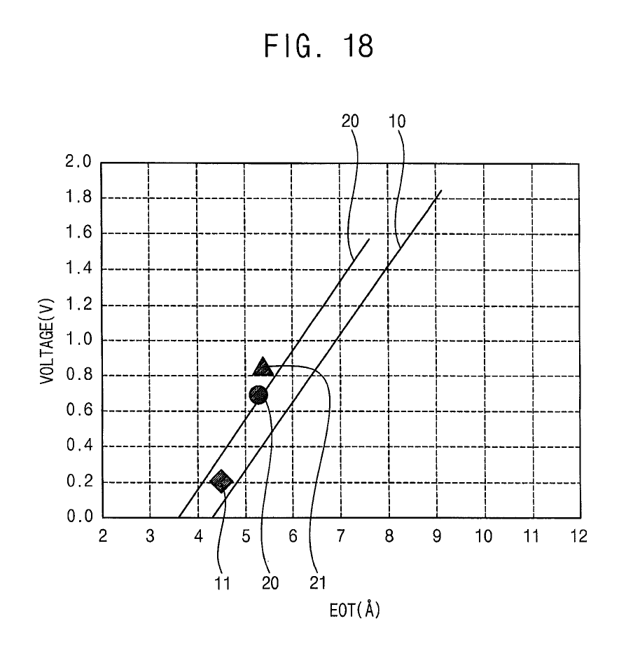

FIG. 17 is a graph showing relations between a voltage applied to capacitor and a leakage current from the capacitor when the first and second embodiments of the capacitor of the present inventive concept and the first to third comparative examples of the conventional capacitors were experimented. FIG. 18 is a graph showing a required voltage with respect to an equivalent oxide thickness (EOT) on condition that the current of about 1×10⁻⁷ A/cm² may path through a capacitor when the first embodiment of the present inventive capacitor and the first comparative example of the conventional capacitor were experimented. In FIGS. 17 and 18, the reference numeral 10 denotes the first comparative example of the conventional capacitor and the reference numeral 11 denotes the second comparative example of the conventional capacitor. In the same way, the reference numeral 13 denotes the third comparative example of the conventional capacitor. In contrast, the reference numeral 20 denotes the first embodiment of the capacitor according to the present inventive concept and the reference numeral 21 denotes the second embodiment of the capacitor according to the present inventive concept.

Referring to FIGS. 17 and 18 shows that the leakage current from the lower electrode was increased when the sputtering process for forming the niobium nitride layer was performed under the composition ratio of argon (Ar) and nitrogen (N2) less than about 1:0.5. In addition, the leakage current is shown to be relatively reduced when the composition ratio of argon (Ar) and nitrogen (N2) was in a range of about 1:1 to about 1:1.2 in FIGS. 17 and 18. Particularly, in case that the current of about 1×10⁻⁷ A/cm² needs to path through a capacitor when about 1V is applied to the capacitor, the EOT of the first embodiment of the present inventive capacitor was smaller than that of the first comparative example of the conventional capacitor as thick as about 0.75 Å.

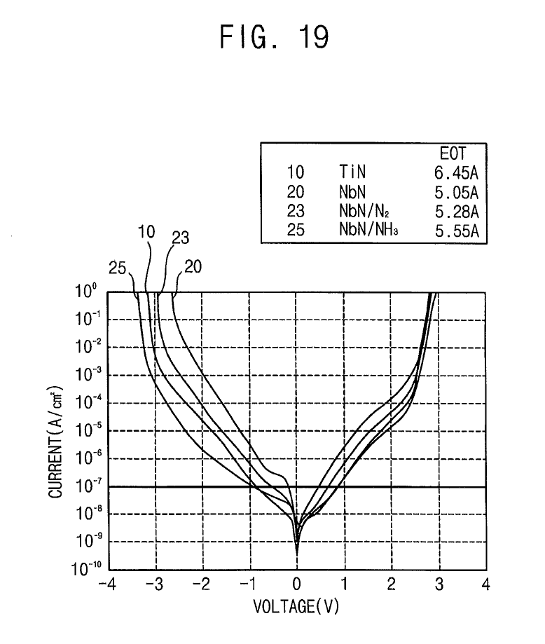

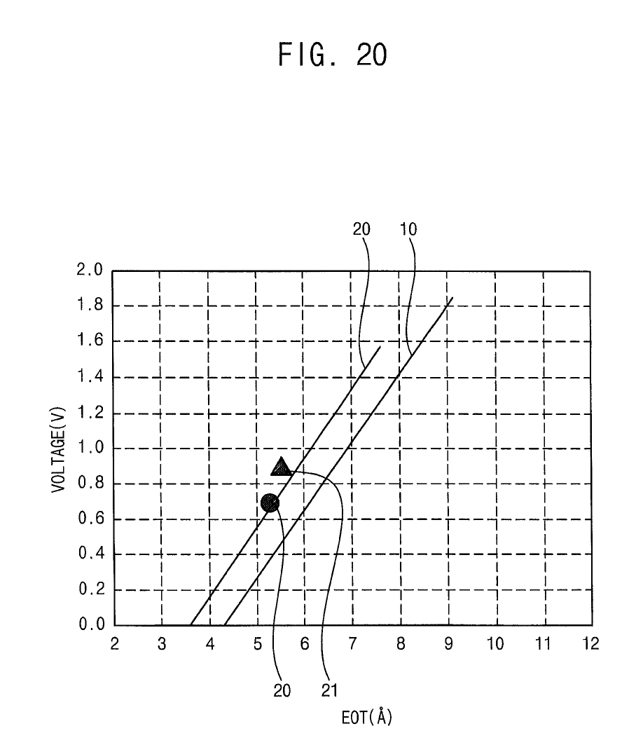

FIG. 19 is a graph showing relations between a voltage applied to capacitor and a leakage current from the capacitor when the first, third and fourth embodiments of the capacitor of the present inventive concept and the first comparative examples of the conventional capacitors were experimented. FIG. 20 is a graph showing a required voltage with respect to an equivalent oxide thickness (EOT) on condition that the current of about 1×10⁻⁷ A/cm² may path through a capacitor when the first, third and fourth embodiment of the present inventive capacitor and the first comparative example of the conventional capacitor were experimented. In FIGS. 19 and 20, the reference numeral 10 denotes the first comparative example of the conventional capacitor and the reference numeral 20, 23 and 25 denote the first, third and fourth embodiments of the capacitor according to the present inventive concept, respectively.

Referring to FIGS. 19 and 20 shows that the leakage current from the lower electrode was increased when the niobium nitride layer experienced the heat treatment in the nitrogen (N2) or ammonium (NH3) atmosphere after formation of the niobium nitride layer. In addition, in case that the current of about 1×10⁻⁷ A/cm² needs to path through a capacitor when about 0.9V is applied to the capacitor, the EOT of the fourth embodiment of the present inventive capacitor was smaller than that of the first comparative example of the conventional capacitor as thick as about 0.9 Å.

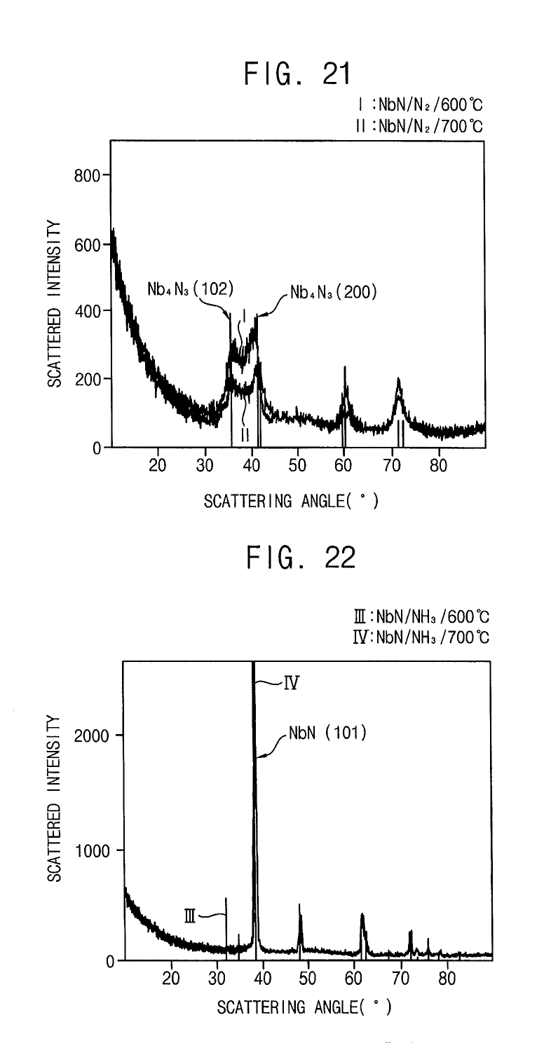

FIGS. 21 and 22 are graphs showing a crystal structure of a niobium nitride layer analyzed by an x-ray diffraction (XRD) inspector. In FIGS. 21 and 22, a horizontal line denotes a scatted angle and a vertical line denotes a scatted intensity of an x-ray beam. FIG. 21 shows the crystallographic structure on the lower electrode of the capacitor under the condition that the heat treatment was performed on the niobium nitride layer at a temperature of about 600° C. to about 700° C. in a nitrogen (N2) gas atmosphere. In contrast, FIG. 22 shows the crystallographic structure on the lower electrode of the capacitor under the condition that the heat treatment was performed on the niobium nitride layer at a temperature of about 600° C. to about 700° C. in an ammonium (NH3) gas atmosphere. Reference numerals I and II denote the niobium nitride layers experiencing the heat treatment at a temperature of about 600° C. and about 700° C., respectively, in nitrogen (N2) gas atmosphere. Reference numerals III and IV denote the niobium nitride layers experiencing the heat treatment at a temperature of about 600° C. and about 700° C., respectively, in an ammonium (NH3) gas atmosphere.

Referring to FIGS. 21 and 22 shows that the niobium nitride layer has a cubic crystal structure or a hexagonal crystal structure due to the heat treatment at a temperature of about 600° C. to about 700° C. in a nitrogen (N2) gas or an ammonium (NH3) gas atmosphere.

According to the example embodiments of the present inventive concept, the multilayer structure includes a conductive layer comprising a metal nitride and a dialectic layer in such a configuration that the metal nitride layer includes vanadium, niobium and compositions thereof. Thus, the multilayer structure in a semiconductor device may sufficiently reduce the EOT and leakage current, to thereby improve electronic characteristics of the semiconductor device. The multilayer structure may be variously applied to electronic devices, for example, to a capacitor, an electrode and a wiring structure of the electronic device, as would be known to one of the ordinary skill in the art.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A multilayer structure comprising:
a conductive layer including a metal nitride, the metal nitride comprising one of niobium, vanadium and compositions thereof; and
a dielectric layer positioned on a surface of the conductive layer and having a high dielectric constant.

2. The multilayer structure of claim 1, wherein the metal nitride includes one of a cubic crystal structure and a hexagonal crystal structure.

3. The multilayer structure of claim 1, wherein a composition ratio of metal and nitrogen is in a range of about 1:0.8 to about 1:1.3.

4. The multilayer structure of claim 1, wherein the dielectric layer includes an oxide or an oxynitride comprising a metal selected from the group consisting of zirconium (Zr), hafnium (Hf), aluminum (Al), silicon (Si), tantalum (Ta), titanium (Ti) and compositions thereof.

5. A capacitor comprising:
a first electrode;
a second electrode facing the first electrode; and
a dielectric layer interposed between the first and second electrodes,
wherein at least one of the first and second electrodes comprises metal nitride including one of vanadium, niobium and compositions thereof.

6. The capacitor of claim 5, wherein the metal nitride includes one of a cubic crystal structure and a hexagonal crystal structure.

7. The capacitor of claim 5, wherein a composition ratio of metal and nitrogen is in a range of about 1:0.8 to about 1:1.3.

8. A method of forming a capacitor, comprising:
forming a lower electrode on a substrate;
forming a dielectric layer on the lower electrode;
forming an upper electrode on the dielectric layer,
wherein at least one of the first and second electrodes comprises metal nitride including one of vanadium, niobium and compositions thereof.

9. The method of claim 8, wherein forming the lower and the upper electrodes includes:
forming a preliminary metal nitride layer on a base; and
nitrified the preliminary metal nitride layer by a heat treatment, to thereby transform the preliminary metal nitride layer to the metal nitride layer.

10. The method of claim 9, wherein the preliminary metal nitride layer is formed by a sputtering process using argon (Ar) gases and nitrogen (N2) gases as a source gas on condition that a composition ratio of argon and nitrogen is in a range of about 1:1 to about 1:2.

11. The method of claim 9, wherein the heat treatment is performed at a temperature of about 200° C. to about 800° C. in a nitrogen gas (N2) or an ammonium (NH3) gas atmosphere.
